(19) United States
(12) Patent Application Publication
(10) Pub. No.: US 2011/0088751 A1
(43) Pub. Date: Apr. 21, 2011

(54) NON-IMAGING RADIANT ENERGY CONCENTRATOR

(76) Inventor: James Rosa, Woodstock, NY (US)

(21) Appl. No.: 12/737,293

(22) PCT Filed: Jun. 29, 2009
(86) PCT No.: PCT/US2009/003849

§ 371 Date: Dec. 27, 2010

Related U.S. Application Data
(60) Provisional application No. 61/133,407, filed on Jun. 30, 2008.

(51) Int. Cl. H01L 31/0232

(52) U.S. Cl. 136/246

(57) ABSTRACT

The invention is a radiant energy trap. As a solar collector it can combine diffuse light concentration and hybrid electric and thermal conversion. A refractor comprises a plurality of non-imaging concentrators, each interfaced with a corresponding receiver, adjacent to a reflector, which can be symmetrical or asymmetrical, with optically independent or dependant sections. The refractor can be a composite of layers, solid or nested fluid layers. The fluid can be a transparent refractive component or be optically independent from the refractive function of the invention and can flow through the refractor as a thermal transfer medium. The refractor can selectively direct radiant energy without reducing the collectors angle of acceptance (AOA) of ambient radiant energy, can take advantage of total internal reflection and can be thermally isolated. The invention has a relatively high concentration (CR) of diffuse light when the AOA is equivalent to that of a flat panel collector.

### TECHNICAL FIELD

The invention is a radiant energy trap. It relates to the field of solar energy and more particularly to electric and thermal conversion diffuse light concentrating solar collectors.

### BACKGROUND ART

Problems associated with the use of fossil fuels, such as global warming, environmental degradation, rising energy costs, peak oil, and global conflicts, have created a need for a solar based economy. Cost competitive solar energy production will probably be required before this goal can be reached. Flat panel solar electric (PV cell) collectors are relatively expensive. Attempts to economize solar energy include concentrating parabolic reflectors that only work in direct sunlight. Even haze or smog reduce the direct sunlight collected. Significant costs are incurred for critical reflector shape, support structure, sun tracking capability, and transmission loss to less sunny regions. Flat panel PV cell collectors are simple to construct, can be stationary and hemi-spherically collect ambient radiant energy, however they operate less efficiently with low level diffuse only light.

Attempts to combine the best of flat panels, and parabolic concentrators include compound parabolic concentrators (CPC). CPCs use reflectors to concentrate (CR) and collect ambient light over a limited angle of acceptance (AOA) according to the ideal 2-D relationship, CR=1/sin(half AOA). CPC reflector's are usually truncated in height, with a reduced CR and collect some light outside the AOA. CPC variants sometimes use transparent refractors. These types of collectors are more generally called radiant energy traps. Designs include those by Eshelman, Knowles, Winston, Gill, Vasylyev, Isofoton S. A., and Sci Tech U.S.A., and European patents EP0070747 and DE 3233081. Refractors are used in designs by Kapany, Johnson, Winston, Lee, Cherney, Fereidooni, Chen, Hines, Poulsen, Kurtz and in Bowden's designs, from the University of New South Wales. The main problem with prior art is that they suffer from a relatively small AOA, or too low a diffuse light CR-AOA combination. The material and manufacturing costs are usually too high for the relative size of the aperture (A) to the refractor size, or reflector area, described as the length of the reflector curve (RL) or height (H), as the ratios; RL/A and H/A respectively. 3-D concentrators, such as those in Steigerwald's patent #DE10059555 A1, Puall's patent application #20050081909, Lichy's patent application #20060072222, Bowden's thesis, Murtha's patents #6021007 and #6619282 also suffer from low CR for the AOA or unreasonably high optics costs, compared to the current invention.

Additional problems with solar power need to be addressed. Installed system payback periods are too long to be generally accepted. In seasonal climates, providing most of a buildings thermal and electrical needs would require an unreasonably large un-shaded solar collector area. PV cell efficiency drops in the hot sun. Even cooled cells waste about 80% of the radiant energy striking them. A hybrid collector combines electric and thermal functions. Numerous hybrid systems have been attempted, as in Mlausky and Winston's patent #4045246, Damsker's patent #4395582, Goldman's patent #4427838, the “CHAPS” project at Australian National University, CPC designs, by Brogren at Uppsala University in Sweden, Puall's patent application #20050081909, Johnson's patent #6080927 or Nicoletti's patent #7173179. These designs have small AOA for the CR, poor energy utilization, require sun tracking or are cost prohibitive relative to the current invention. The present inventor, in WO 2009/005621 A1, which is incorporated herein by reference in its entirety, describes a hybrid, diffuse and direct radiant energy concentrator, solar collector design.

### DISCLOSURE OF INVENTION

The invention is a radiant energy trap comprising at least one reflector, refractor and receiver. The refractor comprises a plurality of non-imaging concentrators, each interfaced with a corresponding receiver section. The refractor has at least one transparent surface that accepts ambient radiant energy and is the aperture for the plurality of non-imaging concentrators. The invention can be used as a hybrid electric and thermal conversion solar collector. The non-imaging concentrators can be, adjacent trough type or 3-D geometries, such as orthogonal pairs of opposing reflectors in a grid formation or hexagonal or cone shaped, in a honeycomb pattern. The receiver can have functions such as a thermal absorber, a detector or transducer. The receiver can have flat opposing faces to support the use of bi-facial photoelectric (PV) cells. Bifacial receivers can utilize a mirror imaged paired refractor. The refractor can be a composite of layers, solid or nested fluid layers. The fluid can be a transparent refractive component or be optically independent from the refractive function of the invention. The fluid can flow through the refractor as a thermal transfer medium. The refractor can be adjacent to a reflector, which can be symmetrical or asymmetrical, with optically independent or dependant sections. The refractor can take advantage of total internal reflection (TIR). The refractor can be thermally isolated. The reflector aperture can be enclosed by a transparent glazing. The reflector-refractor combination can be arrayed. An array can be framed to form a collector module. The invention has a relatively high concentration ratio (CR) of diffuse light for the angle of acceptance (AOA) of ambient radiant energy.

### BRIEF DESCRIPTION OF DRAWINGS

FIG. 1 is a perspective view of an embodiment of the invention.

FIG. 2 is a mirror imaged paired FIG. 1

FIG. 3 is a perspective view of a reduced scale FIG. 2 with mirror image paired, prism shaped apertures.

FIG. 4 is a transverse cross-sectional view of FIG. 3 with an adjacent reflector.

FIG. 5 is a perspective view of an embodiment of the invention with 3-D non-imaging concentrators.

FIG. 6 is a transverse cross-sectional view of a reduced scale, mirror image paired FIG. 5 with an adjacent reflector.

### BEST MODE FOR CARRYING OUT THE INVENTION

The invention is a radiant energy trap comprising at least one reflector, refractor and receiver. The refractor comprises a plurality of non-imaging concentrators interfaced with respective receiver sections. The refractor has at least one transparent surface that accepts ambient radiant energy and is the aperture for the plurality of non-imaging concentrators. The non-imaging concentrators, with their reflective side(s), can be, for example, adjacent trough type or 3-D geometries, such as orthogonal pairs of opposing reflectors in a grid formation or hexagonal or cone shaped, in a honeycomb pattern. The refractor can be a single index of refraction (I-of-R) or be a composite of I-of-R mediums. The refractor can be a composite of layers that are solid or have nested fluid layers. The fluid can be a transparent refractive component, such as water ethylene glycol or mineral oil or be optically independent from the refractive function of the invention by flowing between non-imaging concentrators. The fluid can flow through the refractor as a thermal transfer medium. The refractor can take advantage of total internal reflection (TIR). The refractor can be formed by suitable methods in ways such as cast or extruded, glass or acrylic. The receiver can have functions such as a thermal absorber, a detector or a transducer. The heat transfer fluid can accept thermal energy from the receiver. Bifacial receivers can utilize a mirror imaged paired refractor. The receiver, with flat opposing faces, supports the use of bi-facial photoelectric (PV) cells. The invention can be an electric, thermal or hybrid electric and thermal conversion collector. The refractor can be adjacent to at least one reflector, which can be symmetrical or asymmetrical, with optically dependant or independent sections. The refractor can be thermally isolated. Reflector(s) can be designed with phase space conserving curvatures, which is known to those versed in the art. The reflector(s) can be made of materials such as rear silvered or aluminized acrylic or sun rated clear plastic or front silvered aluminized metal sheet, formed by suitable methods. The reflector-refractor aperture can be enclosed by transparent glazing. The reflector-refractor combination can be arrayed. An array can be framed to form a collector module.

Collector components can be secured by conventional means, being mutually supportive or use scale appropriate supporting members. Collector components can include; a transparent cover plate, end caps, framing, plumbing, electrical connections, suitable thermal isolation and ancillary elements. The invention is a direct and diffuse radiant energy concentrator that can have a relatively high concentration (CR) of diffuse light, while maintaining an angle of acceptance (AOA), of ambient radiant energy, equivalent to a flat panel collector. It can also replace evacuated tube collectors, some parabolic collectors and be used as a secondary for other concentrating collectors.

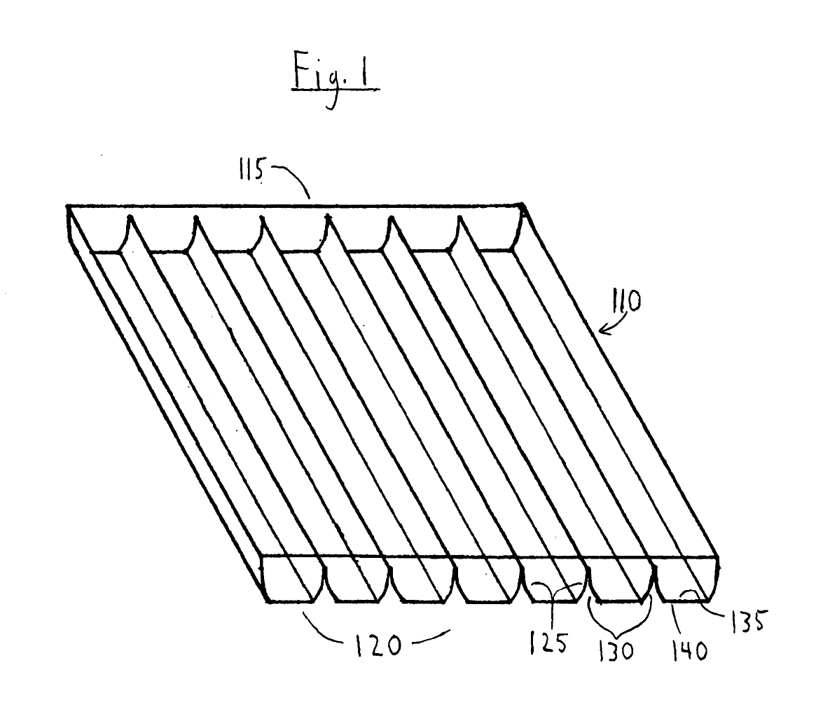

FIG. 1 is a perspective view of an embodiment of the invention. A solid refractor 110 has a flat transparent top surface 115 that is the ambient radiant energy aperture for a plurality of CPC type cross-section troughs 120. Each trough has a pair of opposing sides 125 with facing reflective surfaces 130 and corresponding trough bottom surface 135, with interfaced receiver section 140.

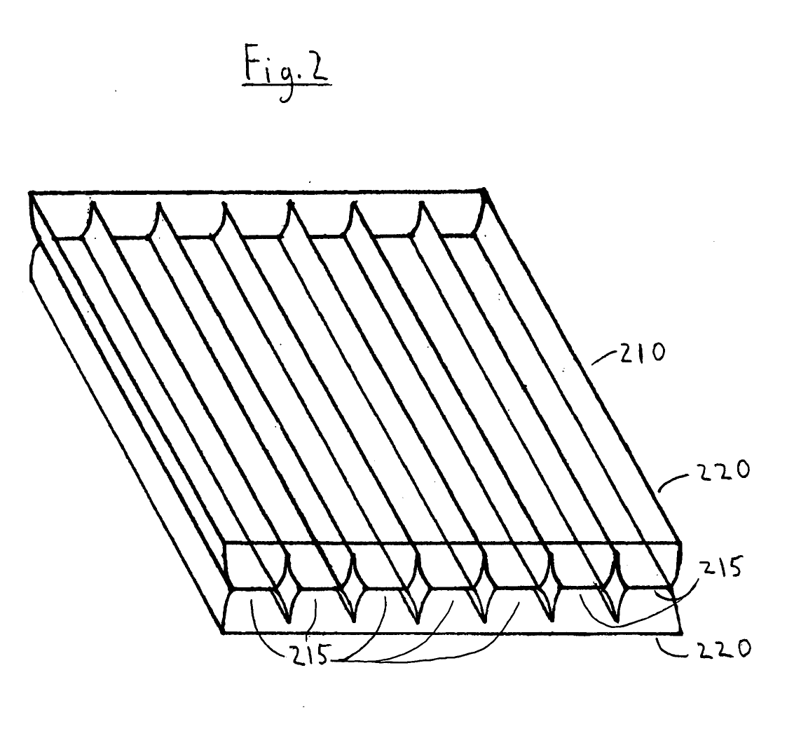

FIG. 2 is a mirror image paired refractor 210 with bifacial receiver sections 215 and opposing flat apertures 220.

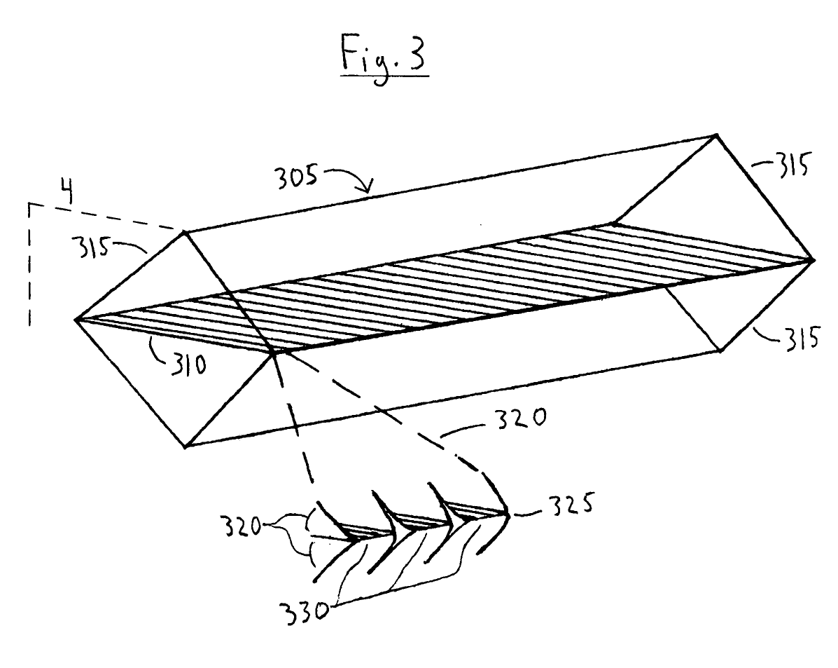

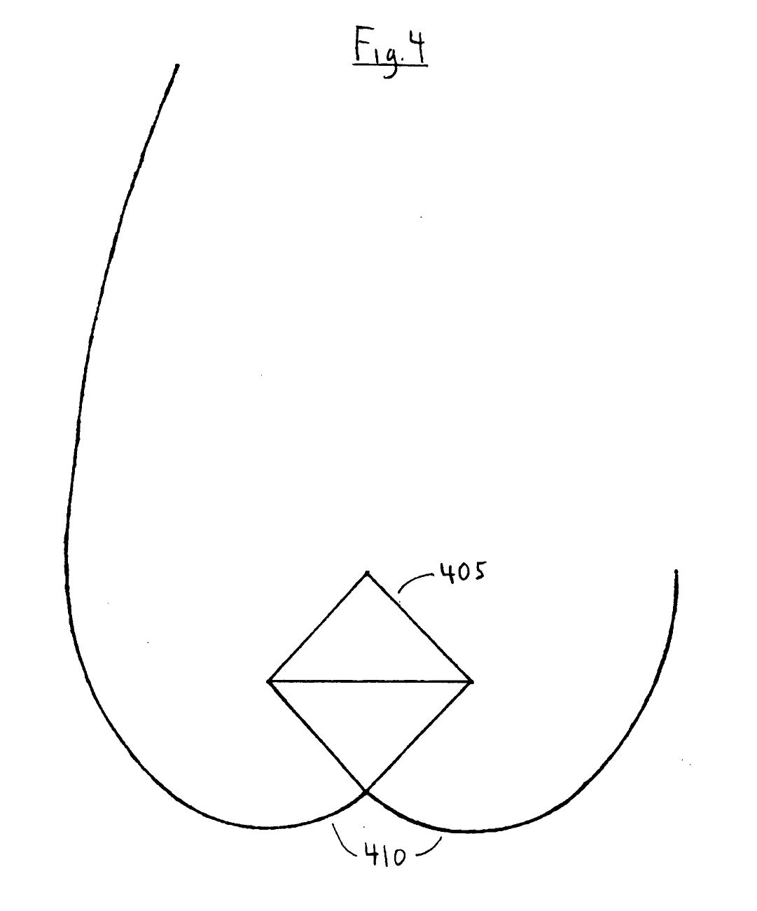

FIG. 3 is a perspective view of a refractor 305 with a reduced scale version of FIG. 2's mirror image paired transverse CPC type troughs 310 having longitudinal, mirror image paired prism shaped apertures 315. An expanded view 320 shows the prism shaped aperture angles 323 and longitudinally adjacent rows of mirror image paired refractor-concentrator troughs' corresponding ends 325 and receiver section ends 330. Cross-section 4 is for FIG. 4.

FIG. 4 is a transverse cross-sectional view of FIG. 3's mirror image paired, prism shaped aperture, refractor-concentrator 405 nested within a transverse cross-section of an adjacent, asymmetrical, optically dependent paired CPC type trough reflector 410.

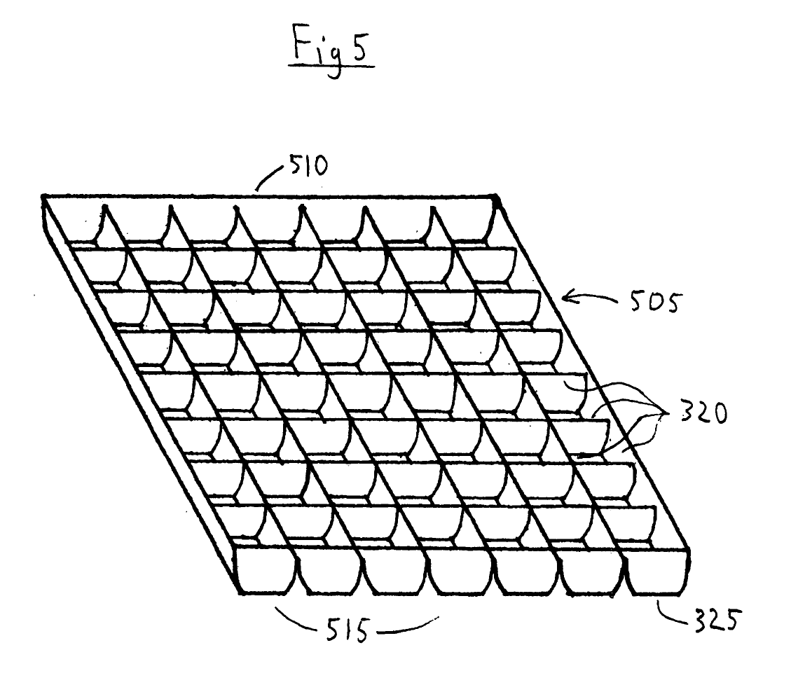

FIG. 5 is a perspective view of an embodiment of the invention. The transparent refractor 505 comprises a flat transparent top surface 510 that is the aperture for a contiguous set or grid of 3-D non-imaging concentrators 515. Each 3-D non-imaging concentrator comprises orthogonally paired CPC type cross-section opposing reflectors 320 with corresponding rectangular bottom receiver sections 325.

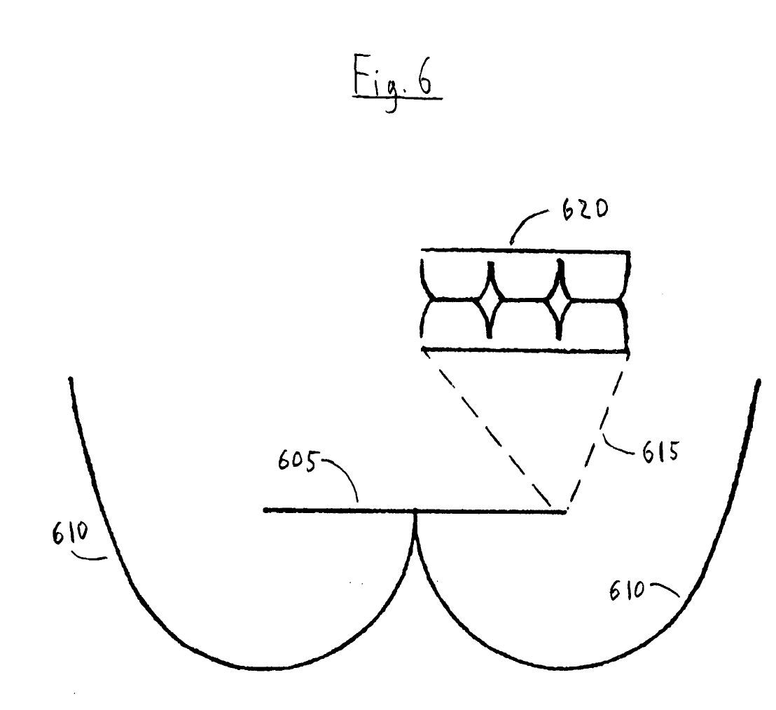

FIG. 6 is a refractor-concentrator edge view 605, as a reduced scale, mirror image paired transverse cross-sectional view version of FIG. 5 that is nested within a transverse cross-section of a symmetrical CPC type trough reflector 610. An expanded view 615 shows a section of mirror image paired contiguous 3-D CPC type refractor-concentrators 620.

The current invention has a significantly higher CR-AOA combination, up to about 5.5 for an E-W 180° and N-S130° AOA, than that claimed by any prior art except for the inventor's and Murtha's. The current invention has much higher efficiency and energy utilization at a much lower optics cost than Murtha has. The refractors' relatively small scale non-imaging concentrators minimize refractor material and cost. There are other possible embodiments of this invention, in addition to the ones described here, for illustrative purposes, including additional elements and ancillary components, without departing from the scope of the invention.

1. I claim a radiant energy trap comprising; at least one reflector, refractor and receiver of said radiant energy; wherein said at least one refractor comprises at least one transparent material, said transparent material comprises at least one non-ambient refractive index (RI), said at least one refractor comprises at least one transparent surface area, wherein said at least one reflector comprises at least one reflector positioned to reflect at least a portion of ambient said radiant energy to at least one of said refractor's at least one transparent surface area, wherein, said at least one refractor comprises a plurality of non-imaging concentrators, said plurality of non-imaging concentrators positioned to accept at least a portion of said radiant energy from said at least one refractors' transparent surface area, wherein said plurality of non-imaging concentrators interface with said at least one receiver of said radiant energy, wherein, said radiant energy trap comprises a radiant energy trap aperture area for said ambient radiant energy.

2. The radiant energy trap of claim 1, wherein said at least one refractor comprises a mirror image paired refractor, said mirror image paired refractor comprises respective halves of mirror image paired said non-imaging concentrators.

3. The radiant energy trap of claim 2, wherein, said mirror image paired non-imaging concentrators comprise a mirror image interface, said at least one receiver comprises at least one bifacial receiver, said mirror image interface comprises said at least one bifacial receiver.

4. The radiant energy trap of claim 3, wherein said mirror image paired non-imaging concentrators comprise mirrored image paired compound parabolic concentrators (CPCs).

5. The radiant energy trap of claim 4, wherein each of said mirror image paired CPCs comprises a corresponding said at least one bifacial receiver, said corresponding bifacial receiver comprises a bifacial photovoltaic (PV) cell, said bifacial PV cell comprises at least one bifacial PV cell, said at least one bifacial PV cell comprises a PV cell area, said radiant energy trap aperture area and said PV cell area comprise a proportional relationship, said proportional relationship comprises a concentration ratio (CR).

6. The radiant energy trap of claim 5 wherein said mirror image paired refractor comprises a solid and fluid material.

7. The radiant energy trap of claim 6, wherein said solid material substantially confines said fluid material for fluid flow means of said fluid material, said fluid material positioned for thermal transfer means with said PV cell area, said fluid material a thermal transfer fluid.

8. The radiant energy trap of claim 7, wherein each mirror image half of said mirror image paired CPCs comprise 2-D CPCs extended in the third dimension as contiguous rows of transverse oriented trough type CPCs.

9. The radiant energy trap of claim 8, wherein each of said transverse oriented trough type CPCs comprise opposed paired said at least one reflector and one face of said bifacial PV cell, wherein each of said opposed paired reflector positioned to direct at least a portion of said radiant energy to a corresponding said one face of said bifacial PV cell.

10. The radiant energy trap of claim 9, wherein said mirror image paired refractor's transparent surface area comprises longitudinally oriented mirror image prism shaped apertures.

11. The radiant energy trap of claim 10, wherein said solid material and said fluid material each comprise an RI, wherein said solid material RI, said fluid material RI and said prism shaped apertures, substantially comprise a shape means for total internal reflection (TIR) of said radiant energy.

12. The radiant energy trap of claim 11, wherein said at least one reflector positioned to reflect at least a portion of ambient said radiant energy to said at least one refractor comprises a longitudinal trough like asymmetrical pair of optically dependent reflector sections, said optically dependent reflector sections contiguous at a longitudinal reflector line, said asymmetrical pair of optically dependent reflector sections nest said mirror image pair refractor prism shaped apertures, said longitudinal reflector line contiguous with a longitudinal line along said mirror image pair refractor prism shaped apertures.

13. The radiant energy trap of claim 12, wherein said longitudinal trough like asymmetrical pair of optically dependent reflector sections and said refractors' longitudinal mirror image pair prism shaped aperture and contiguous rows of transverse oriented trough type CPCs' comprise a shape means for an orthogonal pair of longitudinal and transverse angles of acceptance (AOA) of said radiant energy.

14. The radiant energy trap of claim 13, wherein said transverse AOA subtends about 130°, said longitudinal AOA subtends about 180°, with said CR about five and a half.

15. The radiant energy trap of claim 14, wherein said solid material comprises acrylic and said fluid material comprises mineral oil.

16. The radiant energy trap of claim 7, wherein said mirror image paired refractor's transparent surface area comprises mirror image planar transparent apertures.

17. The radiant energy trap of claim 16, wherein said mirror image paired CPCs comprise a contiguous grid of mirror image paired 3-D CPCs.

18. The radiant energy trap of claim 17, wherein each of said 3-D CPCs comprises transverse and longitudinal, orthogonally paired CPC type reflectors and one face of corresponding said bifacial PV cell.

19. The radiant energy trap of claim 18, wherein corresponding mirror image planar transparent apertures and each of said longitudinal paired CPC type reflectors and each of said transverse paired CPC type reflectors comprises a shape means for about a 180° longitudinal AOA and about a 180° transverse AOA of said radiant energy, respectively.

20. The radiant energy trap of claim 19, wherein, said mirror image pair of contiguous grid 3-D CPCs comprise interstice, said interstice comprise said thermal transfer fluid, said thermal transfer fluid independent of said refractors RI.

21. The radiant energy trap of claim 20, wherein said at least one reflector positioned to reflect at least a portion of ambient said radiant energy to said at least one refractor comprises a symmetrically paired longitudinal trough CPC type reflector, wherein said symmetrically paired longitudinal trough CPC type reflector symmetrically nests said mirror image paired contiguous grid 3-D CPCs' planar transparent apertures, said symmetrically paired longitudinal trough CPC type reflector comprises a longitudinal centerline, said symmetrically paired longitudinal trough CPC type reflector's longitudinal centerline contiguous with a longitudinal centerline along one of said mirror image paired contiguous grid 3-D CPCs, planar refractor's transparent apertures.

22. The radiant energy trap of claim 21, wherein said symmetrically paired, longitudinal trough CPC type reflector and said mirror image paired contiguous grid 3-D CPCs refractor's planar transparent apertures comprise a shape means for longitudinal 180° and transverse 130° AOA, with said CR about five.

23. The radiant energy trap further comprises any of the following; a) fluid confinement or transport structures b) fluid ancillary components c) thermal transport, isolation, conversion or storage components, d) frames or enclosures, e) transparent glazing, f) evacuated space structures, g) electrical conductive or interconnect means or ancillary components, h) transducers detectors, or thermal absorbers, i) optically dependant reflective components j) arrayed configurations, k) mounting or Installation components.
